(19) United States
(12) Patent Application Publication
(10) Pub. No.: US 2016/0118371 A1
(43) Pub. Date: Apr. 28, 2016

(54) SEMICONDUCTOR PACKAGE

(71) Applicant: Samsung Electronics Co., Ltd., Suwon-si (KR)

(72) Inventor: Chul PARK, Seoul (KR)

(21) Appl. No.: 14/733,909

(22) Filed: Jun. 8, 2015

(30) Foreign Application Priority Data
Oct. 23, 2014 (KR) 10-2014-0144284

(51) Int. Cl. H01L 25/18; H01L 25/065; H01L 23/00; H01L 23/498

(52) U.S. Cl. CPC H01L 25/18; H01L 23/49838; H01L 25/0652; H01L 24/17; H01L 2225/06517; H01L 2225/06555; H01L 2224/16227; H01L 2924/1434

(57) ABSTRACT

A semiconductor package includes a package substrate, a first semiconductor chip having a plurality of first connection terminals disposed on a bottom surface thereof, and a second semiconductor chip having a plurality of second connection terminals disposed on a top surface thereof. The first semiconductor chip is stacked on the package substrate so that a first group of connection terminals among the plurality of first connection terminals are combined with the package substrate. The second semiconductor chip is disposed so that the plurality of second connection terminals are combined with a second group of connection terminals among the plurality of first connection terminals.

### CROSS-REFERENCE TO RELATED APPLICATION

This application claims the benefit of Korean Patent Application No. 10-2014-0144284, filed on Oct. 23, 2014, in the Korean Intellectual Property Office, the disclosure of which is incorporated herein in its entirety by reference.

### BACKGROUND

The inventive concept relates to semiconductor packages, and more particularly, to compact and high performance semiconductor packages.

Recently, in the electronics industry, small and light electronic devices are increasingly in demand with the development of mobile systems. In response to such a demand, it may be necessary to reduce the sizes of the electronic devices employed in electronic systems such as mobile systems as well as to encapsulate a plurality of electronic devices in a single package. In particular, as high performance electronic systems require semiconductor devices having a large capacity, it may be necessary to increase the number of semiconductor chips employed in a single semiconductor package. Accordingly, techniques for efficiently disposing semiconductor chips on a package substrate may be necessary to overcome a spatial limitation of the package substrate.

### SUMMARY

The inventive concept provides compact and high performance semiconductor packages.

According to an aspect of the inventive concept, there is provided a semiconductor package. The semiconductor package includes a package substrate, a first semiconductor chip having a plurality of first connection terminals disposed on a bottom surface thereof, and a second semiconductor chip having a plurality of second connection terminals disposed on a bottom surface thereof. The first semiconductor chip is stacked on the package substrate so that a first group of connection terminals among the plurality of first connection terminals are combined with the package substrate. The second semiconductor chip is disposed so that the plurality of second connection terminals are combined with a second group of connection terminals among the plurality of first connection terminals.

In some embodiments, a top surface of the package substrate may be coplanar with a bottom surface of the second semiconductor chip.

In some embodiments, a portion of the first semiconductor chip may overlap with a portion of the package substrate.

In some embodiments, one sidewall of the package substrate may face one sidewall of the second semiconductor chip.

In some embodiments, a planar area of the second semiconductor chip may be less than a planar area of the first semiconductor chip.

In some embodiments, the first semiconductor chip may include a plurality of semiconductor chips. In such a case, the second semiconductor chip may combine with the plurality of first semiconductor chips.

In some embodiments, the first connection terminal and the second connection terminal having the same function may be vertically aligned with each other.

In some embodiments, the first semiconductor chip may be a memory chip.

In some embodiments, the second semiconductor chip may be a controller chip.

In some embodiments, a thickness of the second semiconductor chip may be less than a thickness of the package substrate.

According to another aspect of the inventive concept, there is provided a semiconductor package. The semiconductor package includes a package substrate having a top surface and a bottom surface, a first semiconductor chip having a portion which is attached to the top surface of the package substrate, a second semiconductor chip attached to the other portion of the first semiconductor chip, a third semiconductor chip having a portion which is attached to the bottom surface of the package substrate, and a fourth semiconductor chip attached to the other portion of the third semiconductor chip.

In some embodiments, a non-active surface of the second semiconductor chip may face a non-active surface of the fourth semiconductor chip.

In some embodiments, a sum of a thickness of the second semiconductor chip and a thickness of the fourth semiconductor chip may be less than a thickness of the package substrate.

In some embodiments, each of the second semiconductor chips and the fourth semiconductor chips may include a plurality semiconductor chips. In such a case, the plurality of second semiconductor chips and the plurality of fourth semiconductor chips may be disposed at one or more sides of the package substrate.

In some embodiments, the package substrate may have a cutaway portion.

According to yet another aspect of the inventive concept, there is provided a semiconductor package. The semiconductor package includes a package substrate, a first semiconductor chip having a plurality of first connection terminals disposed on a bottom surface thereof, a second semiconductor chip having a plurality of second connection terminals disposed on a bottom surface thereof, a third semiconductor chip having a plurality of third connection terminals disposed on a bottom surface thereof, and a fourth semiconductor chip having a plurality of fourth connection terminals disposed on a bottom surface thereof. The first semiconductor chip is stacked on a top surface of the package substrate so that a first group of connection terminals among the plurality of first connection terminals are combined with the package substrate. The second semiconductor chip is disposed so that the plurality of second connection terminals are combined with a second group of connection terminals among the plurality of first connection terminals. The third semiconductor chip is stacked on a bottom surface of the package substrate so that a first group of connection terminals among the plurality of third connection terminals are combined with the package substrate. The fourth semiconductor chip is disposed so that the plurality of fourth connection terminals are combined with a second group of connection terminals among the plurality of third connection terminals.

In some embodiments, a non-active surface of the second semiconductor chip may face a non-active surface of the fourth semiconductor chip.

In some embodiments, the first connection terminal and the second connection terminal having the same function may be vertically aligned with each other, and the third connection terminal and the fourth connection terminal having the same function may be vertically aligned with each other.

In some embodiments, a sum of a thickness of the second semiconductor chip and a thickness of the fourth semiconductor chip may be less than a thickness of the package substrate.

In some embodiments, each of the second semiconductor chips and the fourth semiconductor chips may include a plurality semiconductor chips. In such a case, the plurality of second semiconductor chips and the plurality of fourth semiconductor chips may be disposed at one or more sides of the package substrate.

### BRIEF DESCRIPTION OF THE DRAWINGS

Example embodiments of the inventive concept will be more clearly understood from the following detailed description taken in conjunction with the accompanying drawings in which:

FIG. 1 is a schematic view illustrating a method of fabricating a semiconductor package according to an embodiment;

FIGS. 2A and 2B illustrate a cross-sectional view and a plan view of a semiconductor package according to an embodiment, respectively;

FIGS. 3A and 3B illustrate a cross-sectional view and a plan view of a semiconductor package according to another embodiment, respectively;

FIGS. 4A and 4B illustrate a cross-sectional view and a plan view of a semiconductor package according to yet another embodiment, respectively;

FIGS. 5A and 5B illustrate a cross-sectional view and a plan view of a semiconductor package according to still another embodiment, respectively;

FIGS. 6A and 6B illustrate a cross-sectional view and a plan view of a semiconductor package according to yet still another embodiment, respectively;

FIG. 7 is a plan view illustrating a memory module including at least one semiconductor package according to some embodiments;

FIG. 8 is a block diagram illustrating a system including at least one semiconductor package according to some embodiments; and

FIG. 9 is a block diagram illustrating a memory card including at least one semiconductor package according to some embodiments.

### DETAILED DESCRIPTION OF EXAMPLE EMBODIMENTS

Various example embodiments of the inventive concept will now be described more fully hereinafter with reference to the accompanying drawings to better understand configurations and effects of the inventive concept. It should be noted, however, that the inventive concept is not limited to the following example embodiments, and may be implemented in various forms. Rather, these embodiments are provided so that this disclosure will be thorough and complete, and will fully convey the scope of the inventive concept to those skilled in the art. In the drawings, embodiments of the inventive concept are not limited to the specific examples provided herein and are exaggerated for clarity.

It will be understood that when an element such as a layer, region or substrate is referred to as being “on” another element, it can be directly on the other element or intervening elements may be present. In contrast, the term “directly” means that there are no intervening elements. Other words used to describe the relationship between elements or layers should be interpreted in a like fashion (e.g., “between” versus “directly between,” “adjacent” versus “directly adjacent,” “on” versus “directly on”).

It will also be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

As used herein, the singular terms “a,” “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong.

Unless particular expressions are described in the specification, the terms “a vertical direction” and “a horizontal direction” means a direction which is perpendicular to a main surface of a package substrate and a direction which is parallel with the main surface of the package substrate, respectively. Moreover, unless particular expressions are described in the specification, it will be further understood that when a first element is referred to as being on “a top surface” of a second element stacked on a package substrate, the top surface of the second element may correspond to a surface of the second element opposite to the package substrate and a bottom surface of the second element may correspond to a surface of the second element facing the package substrate.

As used herein, the term “and/or” includes any and all combinations of one or more of the associated listed items. In addition, expressions such as “at least one of,” when preceding a list of elements, modify the entire list of elements and do not modify the individual elements of the list.

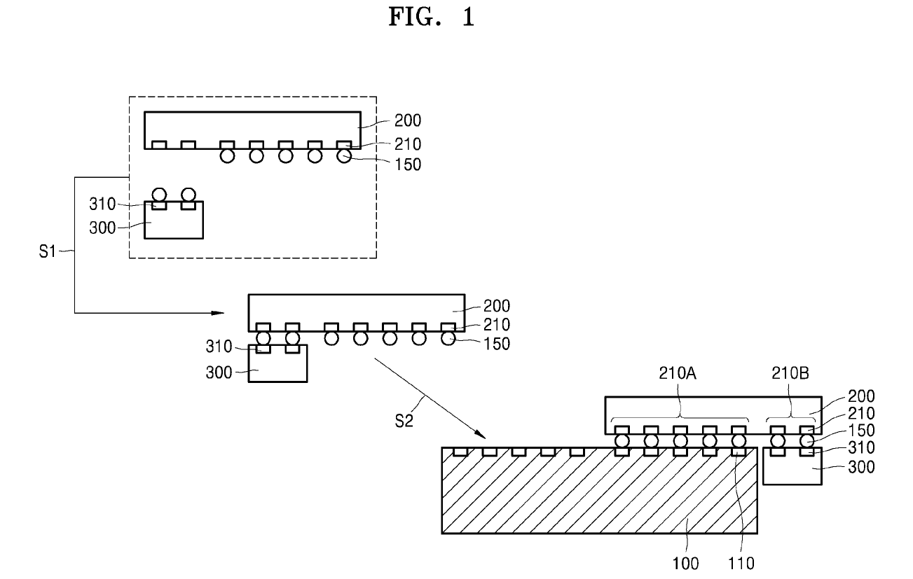

FIG. 1 is a schematic view illustrating a method of fabricating a semiconductor package, according to an embodiment.

FIG. 1 illustrates a step S1 of electrically combining a first semiconductor chip with a second semiconductor chip and a second step S2 of electrically combining the first and second semiconductor chips with a package substrate.

If semiconductor chips are stacked on a package substrate to fabricate a lighter and smaller semiconductor package, there may be a limitation in stacking the semiconductor chips because of a limited thickness of the semiconductor package. In general, controller chips may be stacked on top surfaces of memory chips opposite to a package substrate because the controller chips are smaller than the memory chips. In such a case, bonding wires may be disposed between the controller chips and the package substrate to electrically connect the controller chips to the package substrate. Thus, there may be a limitation in reducing the lengths of the bonding wires. As a result, the delay time of electrical signals transmitted through the bonding wires may increase and thus degrade the performance of the semiconductor package.

However, if each of the controller chips and the memory chips is disposed directly on the package substrate to reduce the delay time of the electrical signals thereof, it may be difficult to reduce a size of the semiconductor package as well as to increase a capacity of the semiconductor package.

Accordingly, an area of a package substrate occupied by a controller chip may be minimized by fabricating the controller chip having a size which is less than a size of the package substrate, by attaching the controller chip to a first portion of a main surface of a memory chip having a size which is greater than a size of the controller chip, and by attaching the package substrate to a second portion of the main surface of the memory chip. As a result, the number of memory chips mounted in a single semiconductor package having a limited thickness may increase.

According to the inventive concept, a first semiconductor chip 200 (e.g., a memory chip) having a relatively large planar area may be provided to have a plurality of first connection terminals 210 including a first group of connection terminals 210A and a second group of connection terminals 210B. The first group of connection terminals 210A of the first semiconductor chip 200 may be attached to a package substrate 100, and the second group of connection terminals 210B of the first semiconductor chip 200 may be attached to a second semiconductor chip 300 (e.g., a controller chip) having a relatively small planar area. In such a case, the number of memory chips mounted on the package substrate 100 may increase, thereby to provide a large capacity of a semiconductor package with a limited thickness.

The package substrate 100 may act as a support substrate including a top surface and sidewalls, and the first semiconductor chip 200 may be disposed on the top surface of the package substrate 100 and the second semiconductor chip 300 may be disposed on the sidewall of the package substrate 100. The package substrate 100 may include a body layer, a lower protection layer, and an upper protection layer. In some embodiments, the package substrate 100 may be any one of a printed circuit board (PCB), a ceramic substrate, a glass substrate, and an interposer substrate. Alternatively, the package substrate 100 may be an active wafer. The active wafer means a wafer such as a silicon wafer on which semiconductor chips are formed.

In a semiconductor package according to these embodiments, the package substrate 100 may be a PCB, for example, a PCB for a molded underfill (MUF) process. However, the package substrate 100 is not limited to the PCB for an MUF process. The MUF process means a process that is performed to encapsulate the first and second semiconductor chips 200 and 300 and to fill spaces between the first and second semiconductor chips 200 and 300 and the package substrate 100 with a resin material using a one-shot molding technique, and a PCB used in the MUF process is referred to as the PCB for an MUF process. Interconnection lines may be disposed on the package substrate 100, and the interconnection lines on the package substrate 100 may be electrically connected to the first and second semiconductor chips 200 and 300 through solder balls, bonding wires, bumps or the like. In addition, external connection members (not shown) may be disposed on a surface of the package substrate 100 opposite to the semiconductor chip 200. The package substrate 100 may be mounted on a module substrate or a system board and may be electrically connected to the system substrate or the system board through the external connection members.

Multi-layered or single-layered interconnection patterns may be disposed in the body layer of the package substrate 100, and the interconnection patterns may electrically connect the external connection members to substrate pads (not shown) on the package substrate 100. The lower and upper protection layers of the package substrate 100 may protect the body layer of the package substrate 100. In some embodiments, the lower and upper protection layers may be formed of a solder resist material.

If the package substrate 100 is a PCB, the body layer of the package substrate 100 may be provided by pressing a resin material such as a phenol resin material or an epoxy glass (FR-4) resin material to form a thin film layer. Moreover, a copper foil may be coated on both sides of the body layer, and the copper foil may be patterned to form the interconnection patterns used as electrical signal paths. In addition, the interconnection patterns on a top surface of the body layer may be electrically connected to the interconnection patterns on a bottom surface of the body layer through via contacts that penetrate the body layer. Furthermore, solder resist layers may be formed on the top and bottom surfaces of the body layer and expose pad portions of the interconnection patterns. The solder resist layer on the top surface of the body layer may correspond to the upper protection layer, and the solder resist layer on the bottom surface of the body layer may correspond to the lower protection layer.

The PCBs may be categorized as either single layer PCBs or double layer PCBs. The interconnection patterns of each single layer PCB may be disposed only on one surface of a body layer of the single layer PCB, and the interconnection patterns of each double layer PCB may be disposed on two opposite surfaces of a body layer of the double layer PCB. In some embodiments, a plurality of copper foils may be stacked on a body layer of the PCB and the plurality of stacked copper foils may be insulated from each other by a prepreg material disposed therebetween. In such a case, the multi-layered interconnection patterns may be provided in the package substrate 100. The package substrate 100 is not limited to the PCB described above. That is, in some other embodiments, the package substrate 100 may be formed of other materials which are different from the aforementioned materials and may be formed to have other structures which are different from the aforementioned structures.

Each of the first and second semiconductor chips 200 and 300 may include a body portion, an interconnection portion, and a passivation layer. Each of the first and second semiconductor chips 200 and 300 may be fabricated using an active wafer.

If each of first and second semiconductor chips 200 and 300 is fabricated using an active wafer, the body portion may include a semiconductor substrate, an integrated circuit layer, and an interlayer insulation layer. In addition, the interconnection portion disposed on the body portion may include an inter-metal insulation layer and a multi-layered interconnection layer disposed in the inter-metal insulation layer.

The semiconductor substrate corresponding to a main part of the body portion may include a Group IV material wafer or a Group III-V compound wafer. In addition, the semiconductor substrate may be a single crystalline wafer such as a single crystalline silicon wafer in terms of crystallography. For example, the semiconductor substrate may be an epitaxial wafer, a polished wafer, an annealed wafer, or a silicon on insulator (SOI) wafer. The epitaxial wafer may correspond to a wafer which is formed by growing a crystalline material on a single crystalline silicon substrate. However, the semiconductor substrate is not limited to a single crystalline wafer.

Although not shown in the drawings, the passivation layer may be disposed on the active surface of the body portion to cover the interconnection portion. The passivation layer may prevent integrated circuits of the first semiconductor chip 200 from being physically and chemically damaged. The passivation layer may be formed to include at least one selected from the group consisting of an oxide layer and a nitride layer. In some embodiments, the passivation layer may be formed using a high density plasma (HDP) chemical vapour deposition (CVD) process. For example, the passivation layer may be formed of at least one selected from the group consisting of a silicon oxide layer and a silicon nitride layer using an HDP-CVD process.

The plurality of first connection terminals 210 may be disposed on the active surface of the first semiconductor chip 200, and a pad may be included in each of the first connection terminals 210. Each of the first connection terminals 210 may include only a copper pillar. Alternatively, each of the first connection terminals 210 may include a copper pillar and a solder material. Some of the first connection terminals 210 may be electrically connected to a plurality of second connection terminals 310 of the second semiconductor chip 300.

Although FIG. 1 illustrates an example in which only the first connection terminals 210 are disposed in the first semiconductor chip 200 and all of the first connection terminals 210 are connected to upper connection terminals 110 of the package substrate 100 and the second connection terminals 310 of the second semiconductor chip 300 for ease of description, the inventive concept is not limited to the embodiment of FIG. 1. That is, in some embodiments, various kinds of pads or connection terminals may be disposed on the active surface of the first semiconductor chip 200.

The first and second semiconductor chips 200 and 300 may include a memory device and a non-memory device. The memory device may be, for example, a dynamic random access memory (DRAM) device, a static random access memory (SRAM) device, a flash memory device, an electrically erasable programmable read only memory (EEPROM) device, a phase changeable random access memory (PRAM) device, a magnetic random access memory (MRAM) device, or a resistive random access memory (RRAM) device. The non-memory device may be a logic device, for example, a microprocessor, a digital signal processor, a microcontroller, or the like.

In some embodiments, the first semiconductor chip 200 may be a memory device such as a flash memory device, and the second semiconductor chip 300 may be a logic device such as a controller.

In some embodiments, the semiconductor package may include a plurality of first semiconductor chips 200 and a plurality of second semiconductor chips 300. As used herein, the singular terms “a,” “an” and “the” are intended to include the plural forms as well, unless the context clearly indicates otherwise.

The second semiconductor chip 300 may also include an active surface and a non-active surface, like the first semiconductor chip 200. The second connection terminals 310 of the second semiconductor chip 300 may be electrically connected to the first connection terminals 210 of the first semiconductor chip 200 through a conductive material such as solder balls 150.

The second semiconductor chip 300 may have substantially the same structure as the first semiconductor chip 200. For example, the second semiconductor chip 300 may be fabricated using an active wafer to include a body portion, an interconnection portion, and a passivation layer. In addition, the body portion may include a semiconductor substrate, an integrated circuit layer, and an interlayer insulation layer. Moreover, the interconnection portion may include an inter-metal insulation layer and a multi-layered interconnection layer disposed in the inter-metal insulation layer. The passivation layer of the second semiconductor chip 300 may be disposed on the active surface of the body portion of the second semiconductor chip 300 to cover the interconnection portion.

The plurality of second connection terminals 310 may be disposed on the active surface of the second semiconductor chip 300, and a pad may be included in each of the second connection terminals 310. Each of the second connection terminals 310 may include a copper pillar and a solder material. If each of the first connection terminals 210 includes a solder material, each of the second connection terminals 310 may include only a copper pillar. In some embodiments, each of the first and second connection terminals 210 and 310 may include a solder material. Each of the first and second connection terminals 210 and 310 is not limited to the above-listed materials.

The semiconductor package may be provided in the form of any one selected from the group consisting of a chip scale package (CSP), a wafer level package (WLP), a ball grid array (BGA) package, a pin grid array (PGA) package, a flip chip package, a through hole package, a direct chip attach (DCA) package, a quad flat package (QFP), a quad flat no-lead (QFN) package, a dual in-line package (DIP), a single in-line package (SIP), a zigzag in-line package (ZIP), a tape carrier package (TCP), a multi-chip package (MCP), a small outline package (SOP), and a through silicon via (TSV) package.

The semiconductor package may be referred to as a semiconductor chip if the semiconductor package corresponds to a portion of a stack semiconductor package. The stack semiconductor package may include at least two semiconductor chips. The first semiconductor chip 200 may be different from the second semiconductor chip 300 in size and function. Each of the first and second semiconductor chips 200 and 300 may have substantially the same configuration as a general semiconductor package.

As described above, each of the first and second semiconductor chips 200 and 300 may be provided in the form of a semiconductor package including a molding compound material. However, in the following embodiments, even though each of the first and second semiconductor chips 200 and 300 is provided in the form of a semiconductor package, each of the first and second semiconductor chips 200 and 300 may be referred to as a semiconductor chip for ease of description.

Hereinafter, various embodiments will be described with reference to the accompanying drawings.

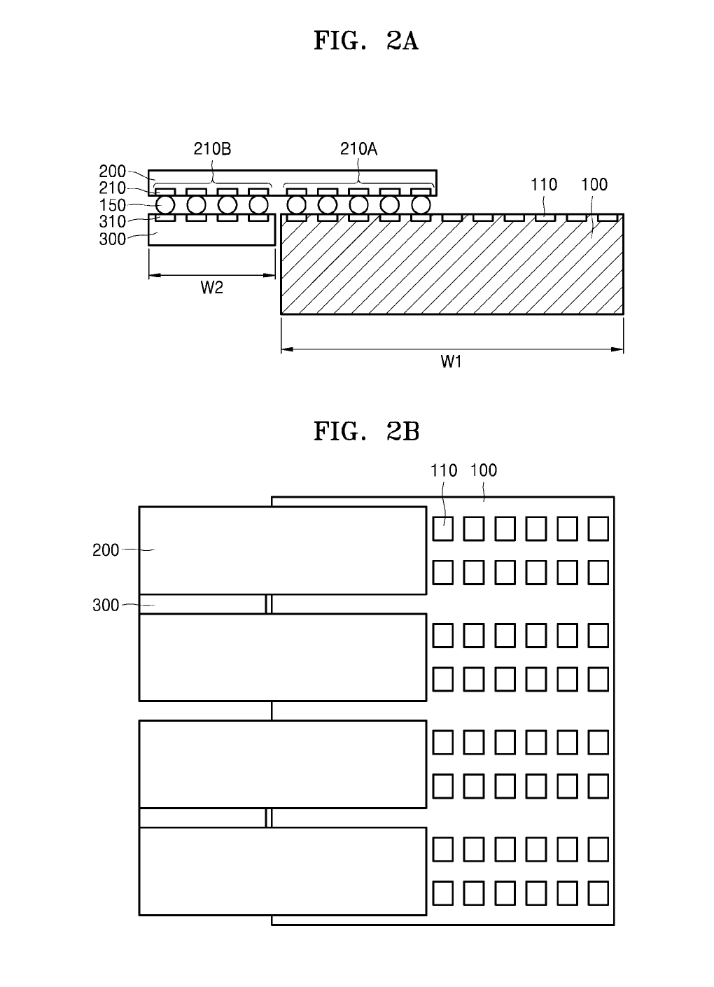

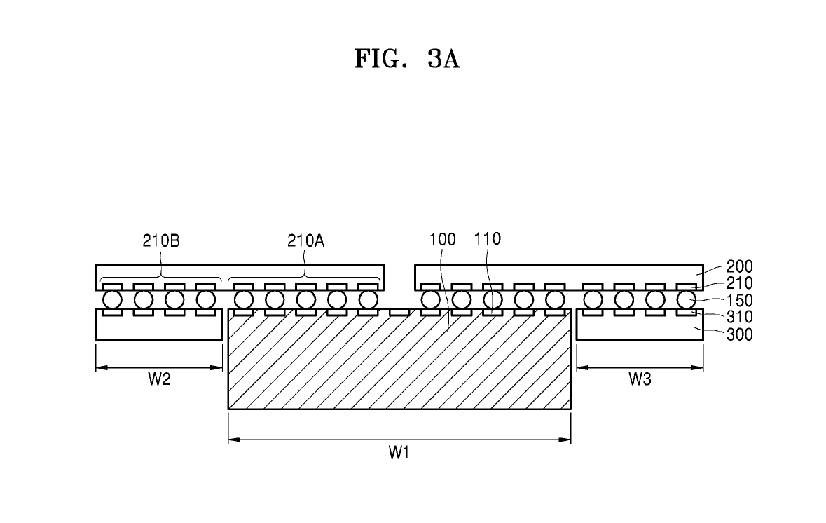

FIGS. 2A, 3A, 4A, 5A, and 6A are cross-sectional views illustrating semiconductor packages according to various embodiments. FIGS. 2B, 3B, 4B, 5B and 6B are plan views corresponding to FIGS. 2A, 3A, 4A, 5A, and 6A, respectively.

FIGS. 2A and 2B illustrate a cross-sectional view and a plan view of a semiconductor package according to an embodiment, respectively. In some embodiments, semiconductor chips may be disposed on one edge of a package substrate.

Referring to FIGS. 2A and 2B, the first semiconductor chip 200 may be mounted on the package substrate 100 so that a portion of the first semiconductor chip 200 overlaps with a portion of the package substrate 100, and the second semiconductor chip 300 may be attached to the other portion of the first semiconductor chip 200 by using the solder balls 150.

A bottom surface of the second semiconductor chip 300 may be coplanar with a top surface of the package substrate 100. That is, the bottom surface of the second semiconductor chip 300 may be at the same level as the top surface of the package substrate 100.

The first connection terminals 210 of the first semiconductor chip 200 that are electrically connected to the package substrate 100 may correspond to the first group of connection terminals 210A, and the first connection terminals 210 of the first semiconductor chip 200 that are electrically connected to the second semiconductor chip 300 may correspond to the second group of connection terminals 210B. An area that the first group of connection terminals 210A occupies may be greater than an area that the second group of connection terminals 210B occupies.

A size of the package substrate 100 may be reduced, as compared with a case that an entire portion of a semiconductor chip is stacked on a package substrate. A sum of a width W1 of the package substrate 100 and a width W2 of the second semiconductor chip 300 may correspond to a total width of a package substrate of a general semiconductor package. That is, the package substrate 100 may be fabricated to have a width which is less than a width of the package substrate used in a general semiconductor package. Accordingly, manufacturing costs of the package substrate 100 may be reduced.

If any one of the first connection terminals 210 and any one of the second connection terminals 310 have the same function, for example, a first function, the first connection terminal 210 and the second connection terminal 310 having the first function may be disposed to be electrically connected to each other. For example, a ground voltage terminal of the first connection terminals 210 and a ground voltage terminal of the second connection terminals 310 may be disposed to be vertically aligned with each other. In such a case, the ground voltage terminal of the second connection terminals 310 may be electrically connected to the package substrate 100 through internal interconnection lines of the first semiconductor chip 200 without use of any bonding wires. Accordingly, a ground voltage signal may be transmitted to the second semiconductor chip 300 without delay due to the bonding wires.

In some embodiments, the semiconductor package may include a plurality of first semiconductor chips 200 and a plurality of second semiconductor chips 300. In such a case, one of the first semiconductor chips 200 may be electrically connected to only one of the second semiconductor chips 300. Alternatively, one of the second semiconductor chips 300 may be electrically connected to two or more of the first semiconductor chips 200. In such a case, the first connection terminals 210 and the second connection terminals 310 having the same function may not be disposed to be vertically aligned with each other. In some other embodiments, the first semiconductor chips 200 may be disposed in different forms according to a size and a function of the second semiconductor chips 300.

External connection members (not shown) may be disposed on a surface of the package substrate 100 opposite to the first semiconductor chips 200. The package substrate 100 may be mounted on a module substrate or a system board through the external connection members.

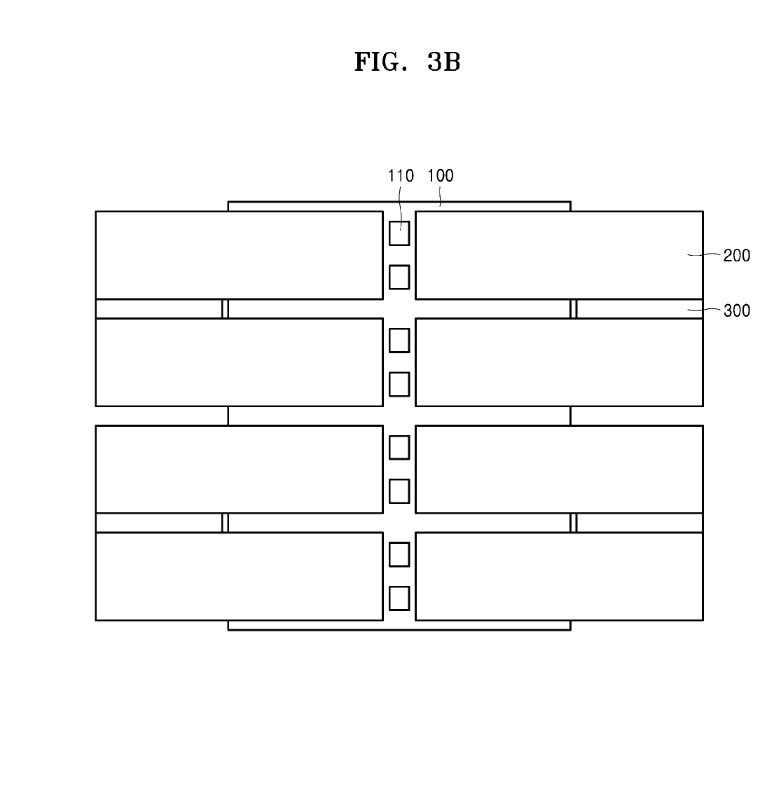

FIGS. 3A and 3B illustrate a cross-sectional view and a plan view of a semiconductor package according to another embodiment, respectively. In some embodiments, semiconductor chips may be disposed on both edges of a package substrate.

Referring to FIGS. 3A and 3B, the first semiconductor chips 200 may be mounted on both edges of the package substrate 100 so that a portion of each of the first semiconductor chips 200 overlaps with a portion of the package substrate 100, and each of the second semiconductor chips 300 may be attached to the other portion of each of the first semiconductor chips 200 by using the solder balls 150.

A size of the package substrate 100 may be reduced, as compared with a case that an entire portion of each semiconductor chip is stacked on a package substrate. A sum of a width W1 of the package substrate 100, a width W2 of the second semiconductor chip 300 disposed at a left side of the package substrate 100, and a width W3 of the second semiconductor chip 300 disposed at a right side of the package substrate 100 may correspond to a total width of a package substrate of a general semiconductor package. That is, the package substrate 100 may be fabricated to have a width which is less than a width of the package substrate used in a general semiconductor package. Accordingly, manufacturing costs of the package substrate 100 may be reduced.

Although FIGS. 3A and 3B illustrate an example in which the second semiconductor chips 300 are disposed at only two opposite sides of the package substrate 100, the inventive concept is not limited thereto. For example, in some embodiments, the second semiconductor chips 300 may be disposed at four sides of the package substrate 100.

The remaining portions of the semiconductor package according to these embodiments may have substantially the same configurations as described with reference to FIGS. 2A and 2B. Thus, descriptions of the remaining portions of the semiconductor package will be omitted hereinafter.

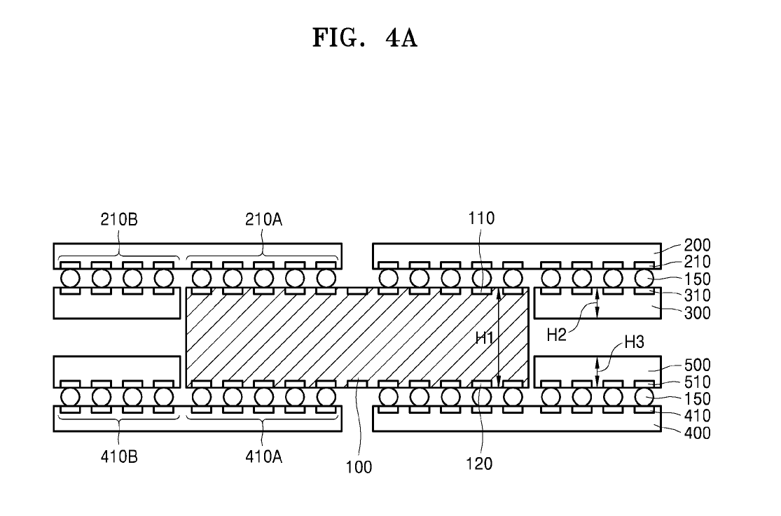

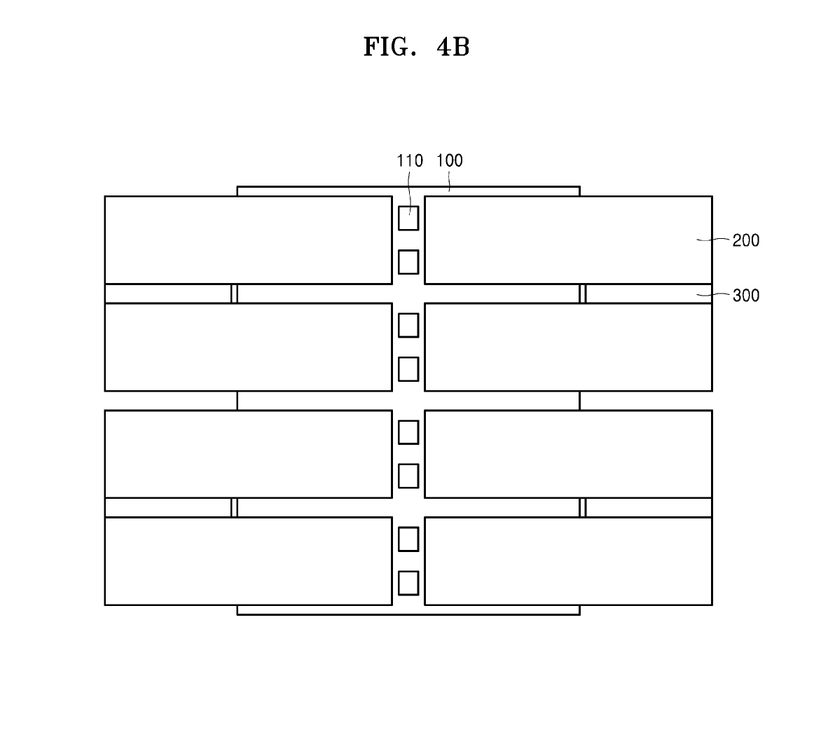

FIGS. 4A and 4B illustrate a cross-sectional view and a plan view of a semiconductor package according to yet another embodiment, respectively. In some embodiments, semiconductor chips may be disposed on top and bottom surfaces of a package substrate.

Referring to FIGS. 4A and 4B, the first semiconductor chips 200 may be mounted on both edges of a top surface of the package substrate 100 so that a portion of each of the first semiconductor chips 200 overlaps with a portion of the package substrate 100, and each of the second semiconductor chips 300 may be attached to the other portion of each of the first semiconductor chips 200 by using the solder balls 150. Similarly, third semiconductor chips 400 may be mounted on both edges of a bottom surface of the package substrate 100 so that a portion of each of the third semiconductor chips 400 overlaps with a portion of the package substrate 100, and each of fourth semiconductor chips 500 may be attached to the other portion of each of the third semiconductor chips 400 by using the solder balls 150.

The upper connection terminals 110 of the package substrate 100 may be electrically connected to the first group of connection terminals 210A among the first connection terminals 210 of the first semiconductor chips 200, and lower connection terminals 120 of the package substrate 100 may be electrically connected to the first group of connection terminals 410A among third connection terminals 410 of the third semiconductor chips 400.

In addition, the second group of connection terminals 210B among the first connection terminals 210 of the first semiconductor chips 200 may be electrically connected to the second connection terminals 310 of the second semiconductor chips 300, and second group of connection terminals 410B among the third connection terminals 410 of the third semiconductor chips 400 may be electrically connected to fourth connection terminals 510 of the fourth semiconductor chips 500.

In the semiconductor package illustrated in FIGS. 4A and 4B, the plurality of semiconductor chips may be stacked on both surfaces of the package substrate 100 to increase a capacity of the semiconductor package. That is, the first and third semiconductor chips 200 and 400 may be respectively stacked on the top and bottom surfaces of the package substrate 100 to increase a capacity of the semiconductor package.

In the embodiment illustrated in FIGS. 4A and 4B, a thickness H1 of the package substrate 100 has to be equal to or greater than a sum of a thickness H2 of the second semiconductor chips 300 and a thickness H3 of the fourth semiconductor chips 500. Otherwise, the second semiconductor chips 300 may collide with the fourth semiconductor chips 500 to cause some failures in an assembly process for fabricating the semiconductor package or to degrade characteristics of the semiconductor package.

The second semiconductor chips 300 and the fourth semiconductor chips 500 may be disposed so that non-active surfaces of the second semiconductor chips 300 face non-active surfaces of the fourth semiconductor chips 500. That is, active surfaces of the second semiconductor chips 300 may be attached to the first semiconductor chips 200, and active surfaces of the fourth semiconductor chips 500 may be attached to the third semiconductor chips 400. Thus, the non-active surfaces of the second semiconductor chips 300 may face the non-active surfaces of the fourth semiconductor chips 500, as illustrated in FIG. 4A.

In some embodiments, one of the second semiconductor chips 300 may be electrically connected to only one of the first semiconductor chips 200. Alternatively, one of the second semiconductor chips 300 may be electrically connected to two or more of the first semiconductor chips 200. In such a case, the first connection terminals 210 and the second connection terminals 310 having the same function may not be disposed to be vertically aligned with each other.

In some embodiments, one of the fourth semiconductor chips 500 may be electrically connected to only one of the third semiconductor chips 400. Alternatively, one of the fourth semiconductor chips 500 may be electrically connected to two or more of the third semiconductor chips 400. In such a case, the third connection terminals 410 of the third semiconductor chips 400 and the fourth connection terminals 510 of the fourth semiconductor chips 500 having the same function may not be disposed to be vertically aligned with each other. In some other embodiments, the first and third semiconductor chips 200 and 400 may be disposed in different forms according to sizes and functions of the second and fourth semiconductor chips 300 and 500.

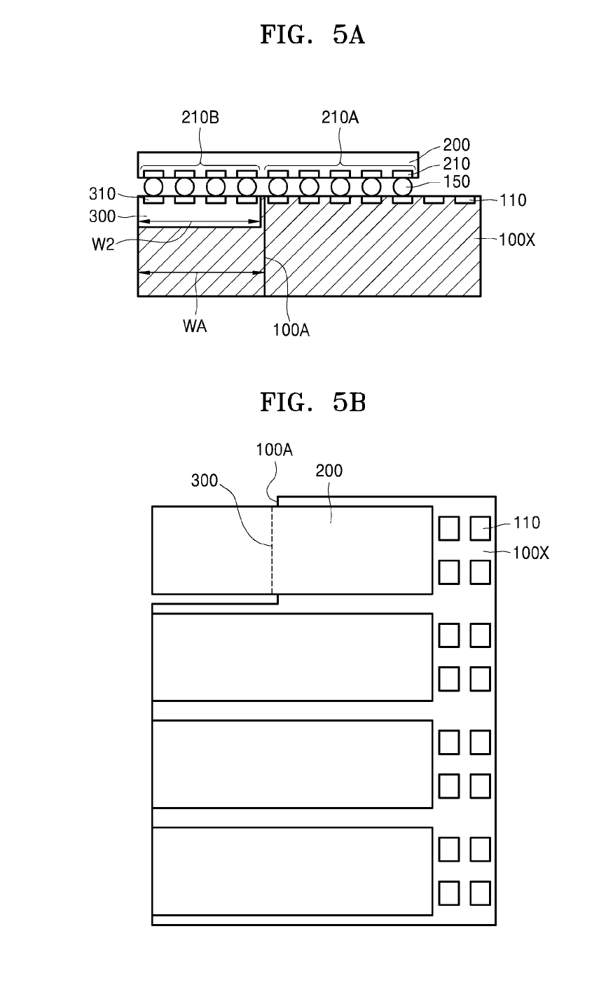

FIGS. 5A and 5B illustrate a cross-sectional view and a plan view of a semiconductor package according to still another embodiment, respectively. In some embodiments, at least one semiconductor chip may be disposed in a cutaway portion of a package substrate.

Referring to FIGS. 5A and 5B, at least a portion (e.g., a corner portion) of a package substrate 100X may be removed to provide a cutaway portion 100A. That is, the package substrate 100X used in the embodiment may have non-rectangular shape by taking into account the disposing of other electronic devices. If a width WA of the cutaway portion 100A is greater than a width W2 of the second semiconductor chip 300, the second semiconductor chip 300 may be disposed in the cutaway portion 100A. In such a case, any one of the first semiconductor chips 200 may be mounted on the package substrate 100X so that the second group of connection terminals 210B of the first semiconductor chip 200 may be located over the cutaway portion 100A, and the second semiconductor chip 300 connected and attached to the second group of connection terminals 210B of the first semiconductor chip 200 may be disposed in the cutaway portion 100A to improve an efficiency of disposing the semiconductor chips.

Although FIGS. 5A and 5B illustrate an example in which the package substrate 100X has only one cutaway portion 100A, the inventive concept is not limited thereto. That is, the package substrate 100X may have two or more cutaway portions. For example, the package substrate 100X may have a “ [symbol] ”-shaped form, “ [symbol] ”-shaped form or a cross-shaped form in a plan view. Disposing of the first and second semiconductor chips 200 and 300 may be different depending on a shape of the package substrate 100X.

In some embodiments, semiconductor chips may be additionally disposed on the bottom surface of the package substrate 100X, as described with reference to FIGS. 4A and 4B.

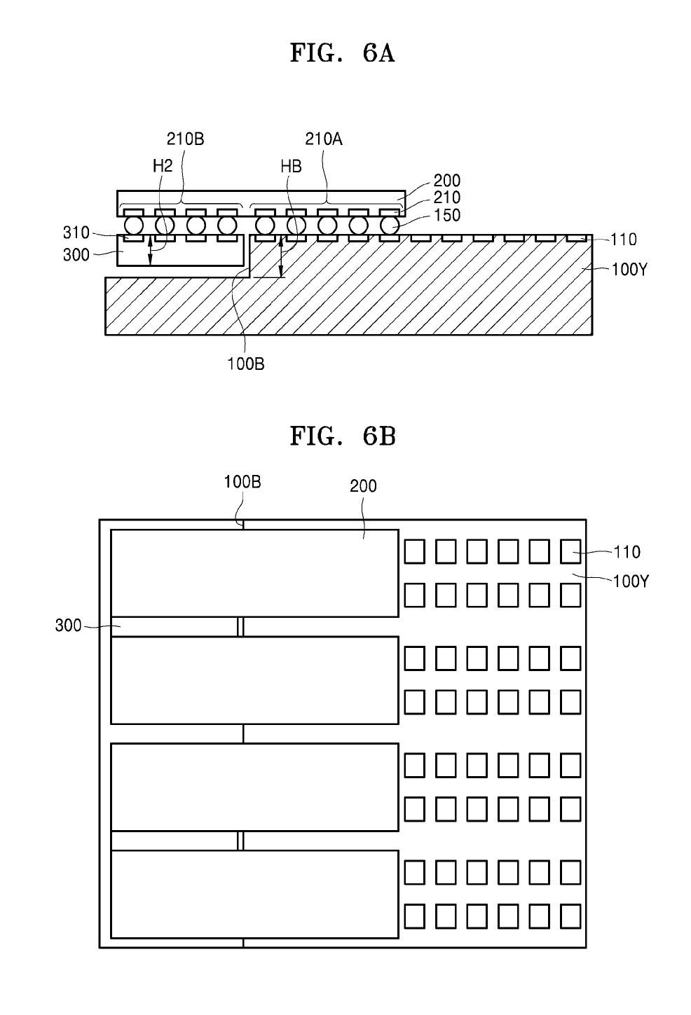

FIGS. 6A and 6B illustrate a cross-sectional view and a plan view of a semiconductor package according to yet still another embodiment, respectively. According to these embodiments, at least one semiconductor chip may be disposed in a recess portion of a package substrate.

Referring to FIGS. 6A and 6B, a package substrate 100Y may have a recess portion 100B in one edge thereof. If a height HB of the recess portion 100B is greater than a thickness H2 of the second semiconductor chips 300, the second semiconductor chips 300 may be disposed in the recess portion 100B. In such a case, the first semiconductor chips 200 may be mounted on the package substrate 100Y so that the second group of connection terminals 210B of the first semiconductor chips 200 may be located over the recess portion 100B, and the second semiconductor chips 300 connected and attached to the second group of connection terminals 210B of the first semiconductor chips 200 may be disposed in the recess portion 100B to improve an efficiency of disposing the semiconductor chips.

Although FIGS. 6A and 6B illustrate an example in which the recess portion 100B is disposed only in one edge of the package substrate 100Y, the inventive concept is not limited thereto. That is, the recess portion 100B may be disposed in two or more edges of the package substrate 100Y. Disposing of the first and second semiconductor chips 200 and 300 may be different depending on a shape of the package substrate 100Y.

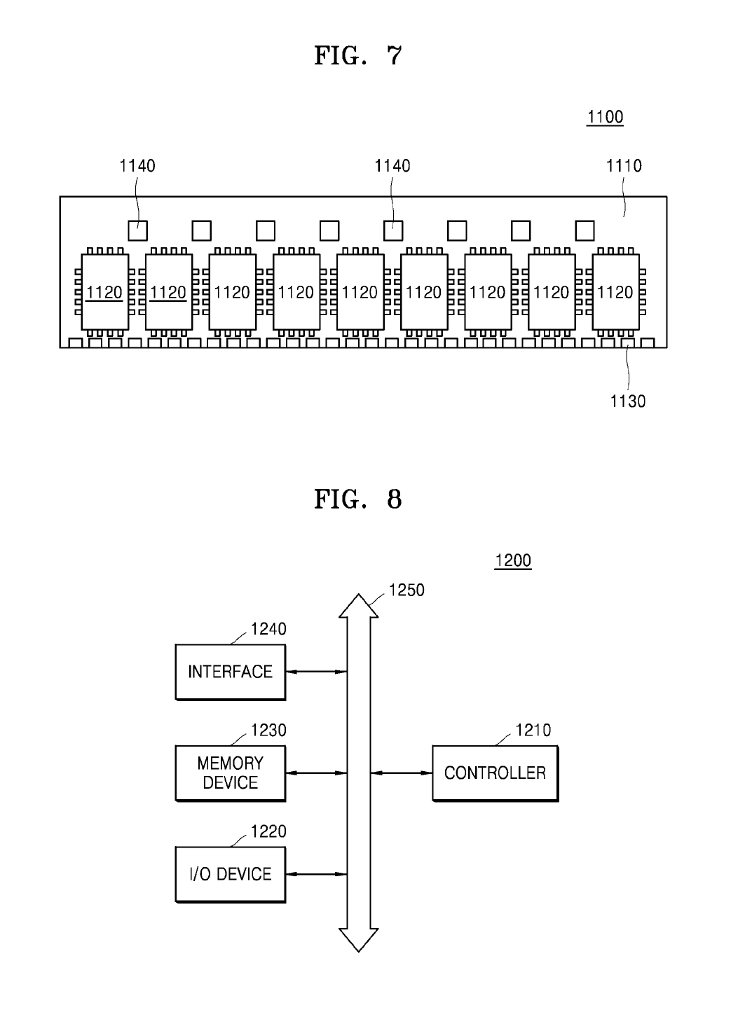

FIG. 7 is a plan view illustrating a memory module 1100 including at least one semiconductor package according to some embodiments.

Referring to FIG. 7, the memory module 1100 may include a module substrate 1110 and a plurality of semiconductor packages 1120 attached to the module substrate 1110.

At least one of the semiconductor packages 1120 may correspond to any one of the semiconductor packages according to the above embodiments. For example, the semiconductor packages 1120 may include at least one of the semiconductor packages described with reference to FIGS. 2A to 6B.

A plurality of connectors 1130 may be disposed on one edge of the module substrate 1110, and the plurality of connectors 1130 may be inserted into a socket of a main board. A plurality of ceramic decoupling capacitors 1140 may be disposed on the module substrate 1110. The memory module 1100 is not limited to the configuration illustrated in FIG. 7. That is, the memory module 1100 may be embodied in many different forms.

FIG. 8 is a block diagram illustrating a system 1200 including at least one semiconductor package according to some embodiments.

Referring to FIG. 8, the system 1200 may include a controller 1210, an input/output (I/O) device 1220, a memory device 1230, and an interface 1240. The system 1200 may be a mobile system that receives and/or outputs information data. In some embodiments, the mobile system may be a personal digital assistant (PDA), a portable computer, a web tablet, a wireless phone, a mobile phone, a digital music player, or a memory card.

The controller 1210 may execute programs and may control overall operations of the system 1200. The controller 1210 may be, for example, a microprocessor, a digital signal processor (DSP), a micro-controller, or the like.

The I/O device 1220 may be used to input data to the system 1200 or to output the data stored in the system 1200. The system 1200 may be connected to an external device or an external system through the I/O device 1220 to communicate with the external device or the external system. The I/O device 1220 may be, for example, a keypad, a keyboard, or a display unit.

The memory device 1230 may store codes and/or data for operations of the controller 1210 or may store data that are processed by the controller 1210. The memory device 1230 may include at least one of the semiconductor packages according to the embodiments of the inventive concept. For example, the memory device 1230 may include at least one of the semiconductor packages illustrated in FIGS. 2A to 6B.

The interface 1240 may provide a data transmission path between the system 1200 and an external device or an external system. The controller 1210, the I/O device 1220, the memory device 1230, and the interface 1040 may communicate with each other through a bus 1250.

The system 1200 may be applied to a mobile phone, an MP3 player, a navigation system, a portable multimedia player (PMP), a solid state disk (SSD), or a household appliance.

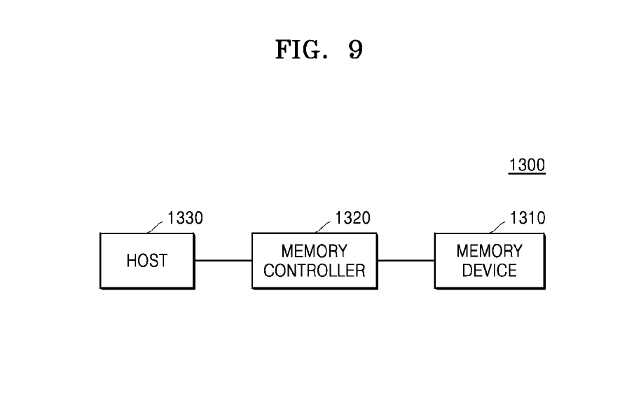

FIG. 9 is a block diagram illustrating a memory card 1300 including at least one semiconductor package according to some embodiments.

Referring to FIG. 9, the memory card 1300 may include a memory device 1310 and a memory controller 1320.

The memory device 1310 may store data. In some embodiments, the memory device 1310 may include at least one non-volatile memory device that retains its stored data even when its power supply is interrupted. The memory device 1310 may include at least one of the semiconductor packages according to the embodiments. For example, the memory device 1310 may include at least one of the semiconductor packages illustrated in FIGS. 2A to 6B.

The memory controller 1320 may control the memory device 1310 so that data is stored in the memory device 1310 or the data stored in the memory device 1310 is read out in response to a read/write request from a host 1330.

While the inventive concept has been particularly shown and described with reference to exemplary embodiments thereof, it will be understood that various changes in form and details may be made therein without departing from the spirit and scope of the following claims.

What is claimed is:

1. A semiconductor package comprising:
a package substrate;
a first semiconductor chip having a plurality of first connection terminals disposed on a bottom surface thereof; and
a second semiconductor chip having a plurality of second connection terminals disposed on a bottom surface thereof,
wherein the first semiconductor chip is stacked on the package substrate so that a first group of connection terminals among the plurality of first connection terminals are electrically combined with the package substrate, and
wherein the second semiconductor chip is disposed so that the plurality of second connection terminals are electrically combined with a second group of connection terminals among the plurality of first connection terminals.

2. The semiconductor package of claim 1, wherein a top surface of the package substrate is coplanar with a bottom surface of the second semiconductor chip.

3. The semiconductor package of claim 1, wherein a portion of the first semiconductor chip overlaps with a portion of the package substrate.

4. The semiconductor package of claim 1, wherein one sidewall of the package substrate faces one sidewall of the second semiconductor chip.

5. The semiconductor package of claim 1, a planar area of the second semiconductor chip is less than a planar area of the first semiconductor chip.

6. The semiconductor package of claim 1,
wherein the first semiconductor chip includes a plurality of semiconductor chips; and
wherein the second semiconductor chip electrically combines with the plurality of first semiconductor chips.

7. The semiconductor package of claim 1, wherein the first connection terminal and the second connection terminal having the same function are vertically aligned with each other.

8. The semiconductor package of claim 1, wherein the first semiconductor chip is a memory chip.

9. The semiconductor package of claim 1, wherein the second semiconductor chip is a controller chip.

10. The semiconductor package of claim 1, wherein a thickness of the second semiconductor chip is less than a thickness of the package substrate.

11. A semiconductor package comprising:
a package substrate having a top surface and a bottom surface;
a first semiconductor chip having a portion which is attached to the top surface of the package substrate;
a second semiconductor chip attached to the other portion of first semiconductor chip;
a third semiconductor chip having a portion which is attached to the bottom surface of the package substrate; and
a fourth semiconductor chip attached to the other portion of third semiconductor chip.

12. The semiconductor package of claim 11, wherein a non-active surface of the second semiconductor chip faces a non-active surface of the fourth semiconductor chip.

13. The semiconductor package of claim 11, wherein a sum of a thickness of the second semiconductor chip and a thickness of the fourth semiconductor chip is less than a thickness of the package substrate.

14. The semiconductor package of claim 11,
wherein each of the second semiconductor chip and the fourth semiconductor chip includes a plurality semiconductor chips; and
wherein the plurality of second semiconductor chips and the plurality of fourth semiconductor chips are disposed at one or more sides of the package substrate.

15. The semiconductor package of claim 11, wherein the package substrate has a cutaway portion.

16. A semiconductor package comprising:
a package substrate;
a first semiconductor chip having a plurality of first connection terminals disposed on a bottom surface thereof;
a second semiconductor chip having a plurality of second connection terminals disposed on a bottom surface thereof;
a third semiconductor chip having a plurality of third connection terminals disposed on a bottom surface thereof; and
a fourth semiconductor chip having a plurality of fourth connection terminals disposed on a bottom surface thereof,
wherein the first semiconductor chip is stacked on a top surface of the package substrate so that a first group of connection terminals among the plurality of first connection terminals are electrically combined with the package substrate,
wherein the second semiconductor chip is disposed so that the plurality of second connection terminals are electrically combined with a second group of connection terminals among the plurality of first connection terminals,
wherein the third semiconductor chip is stacked on a bottom surface of the package substrate so that a first group of connection terminals among the plurality of third connection terminals are electrically combined with the package substrate, and
wherein the fourth semiconductor chip is disposed so that the plurality of fourth connection terminals are electrically combined with a second group of connection terminals among the plurality of third connection terminals.

17. The semiconductor package of claim 16, wherein a non-active surface of the second semiconductor chip faces a non-active surface of the fourth semiconductor chip.

18. The semiconductor package of claim 16,
wherein the first connection terminal and the second connection terminal having the same function are vertically aligned with each other; and
wherein the third connection terminal and the fourth connection terminal having the same function are vertically aligned with each other.

19. The semiconductor package of claim 16, wherein a sum of a thickness of the second semiconductor chip and a thickness of the fourth semiconductor chip is less than a thickness of the package substrate.

20. The semiconductor package of claim 16,
wherein each of the second semiconductor chip and the fourth semiconductor chip includes a plurality semiconductor chips; and
wherein the plurality of second semiconductor chips and the plurality of fourth semiconductor chips are disposed at one or more sides of the package substrate.
